(19) United States
(12) Patent Application Publication
(10) Pub. No.: US 2009/0063061 A1
(43) Pub. Date: Mar. 5, 2009

(54) MONITORING DEGRADATION OF CIRCIUT SPEED

(75) Inventors: RONALD J. BOLAM, East Fairfield, VT (US); Keith A. Jenkins, Sleepy Hollow, NY (US); Kevin G. Stawiasz, Bethel, CT (US)

Correspondence Address: FLEIT GIBBONS GUTMAN BONGINI & BIANCO P.L., 551 NW 77TH STREET, SUITE 111, BOCA RATON, FL, 33487, US

(73) Assignee: INTERNATIONAL BUSINESS MACHINES CORPORATION, ARMONK, NY (US)

(21) Appl. No.: 11/847,426

(22) Filed: Aug. 30, 2007

(51) Int. Cl. G01R 31/3193

(52) U.S. Cl. 702/58; 324/769

(57) ABSTRACT

A circuit, method, and computer readable medium that enables on-chip monitoring of transistor degradation. The circuit includes an on-chip reference ring oscillator electrically coupled to an on-chip reference counter. An on-chip stressed ring oscillator is electrically coupled to an on-chip test counter. A test enable input is electrically coupled with the reference counter, the test counter, and the reference ring oscillator. When the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter. A difference in bit sequence between the reference counter and the test counter is compared to determine a relative difference there between.

### FIELD OF THE INVENTION

The present invention generally relates to the field of electronic circuits, and more particularly relates to monitoring degradation of transistors within a circuit.

### BACKGROUND OF THE INVENTION

Many Complementary Metal Oxide Semiconductor (“CMOS”) transistors experience a reduction of drive current after being operated for many hours, particularly at elevated temperatures. The most notable mechanism for this degradation in contemporary technology is that of negative bias temperature instability (“NBTI”). During the course of normal operation, the Positive Channel Field Effect Transistor (“pFET”) in a CMOS circuit frequently experiences a negative gate to body bias voltage. The result of this bias is a gradual increase in the pFET threshold voltage with a corresponding reduction in the drive current. This, in turn, leads to slower switching speeds in the affected circuits. After prolonged periods of constant operation, the operating speed of the circuit is gradually reduced, thereby potentially leading to failure.

Therefore a need exists to measure and overcome the problems with the prior art as discussed above.

### SUMMARY OF THE INVENTION

Briefly, in accordance with the present invention, disclosed are a circuit, method, and computer readable medium for monitoring on-chip or on-product transistor degradation. The circuit includes an on-chip reference ring oscillator electrically coupled to an on-chip reference counter. An on-chip stressed ring oscillator is electrically coupled to an on-chip test counter. An on-chip test enable input is electrically coupled with the reference counter, the test counter, and the reference ring oscillator. In another embodiment, the test enable input, could be place external or “off chip.” When the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter. A difference in bit sequence between the reference counter and the test counter is compared to determine a relative frequency difference there between.

In another embodiment, a method for monitoring transistor degradation is disclosed. The method includes electrically coupling an on-chip reference ring oscillator to an on-chip reference counter. An on-chip stressed ring oscillator is electrically coupled to an on-chip test counter. A test enable input is electrically coupled with the reference counter, the test counter, and the reference ring oscillator. The test enable input is asserted. When the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter. A difference in bit sequence between the reference counter and the test counter is compared. A relative difference between the frequency of the reference counter and the frequency of the test counter is determined in response to the comparing.

In yet another embodiment, a computer readable medium for monitoring transistor degradation is disclosed. The computer readable medium comprises instructions for electrically coupling a reference ring oscillator to a reference counter. A stressed ring oscillator is electrically coupled to a test counter. A test enable input is electrically coupled with the reference counter, the test counter, and the reference ring oscillator. The test enable input is asserted. When the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter. A difference in bit sequence between the reference counter and the test counter is compared. A relative difference between the frequency of the reference counter and the frequency of the test counter is determined in response to the comparing.

One advantage of the present invention is transistor degradation can be monitored on-chip. The present invention allows for the detection and reporting of transistor speed degradation in field-installed transistors. This provides a real-time measure of transistor degradation. The present invention measures the frequency of a constantly or frequently powered ring oscillator on a chip and compares that measurement to a measurement taken from a ring oscillator only powered during testing. The frequencies can be converted to digital form and stored in internal registers on the chip, thereby allowing the degradation to be tracked over the lifetime of the chip.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is a schematic of a circuit for monitoring transistor degradation according to an embodiment of the present invention;

FIG. 2 is a schematic of another circuit for monitoring transistor degradation according to an embodiment of the present invention;

FIG. 3 is a schematic of a circuit for supplying power to the circuits of FIG. 1 and FIG. 2 according to an embodiment of the present invention;

FIG. 4 is a schematic of a circuit for selecting an Alternating Current (AC) test mode of a Direct Current (DC) test mode for the circuits of FIG. 1 and FIG. 2 according to an embodiment of the present invention;

FIG. 5 is an operational flow diagram illustrating monitoring transistor degradation in a circuit.

### DETAILED DESCRIPTION

The present invention as would be known to one of ordinary skill in the art could be produced as part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

The term “on-chip” is used to denote that the circuitry is formed with other circuitry on the integrated circuit chip with the goal of integrating all components of an electronic system into a single integrated circuit (chip). Conversely, the term “off-chip” means the circuity is formed independent of the other circuitry on the integrated chip.

The measurements are made on-chip and the results stored on-chip in digital form. No external output pins or test equipment are required to make measurements.

Exemplary Circuits For Monitoring Transistor Degradation

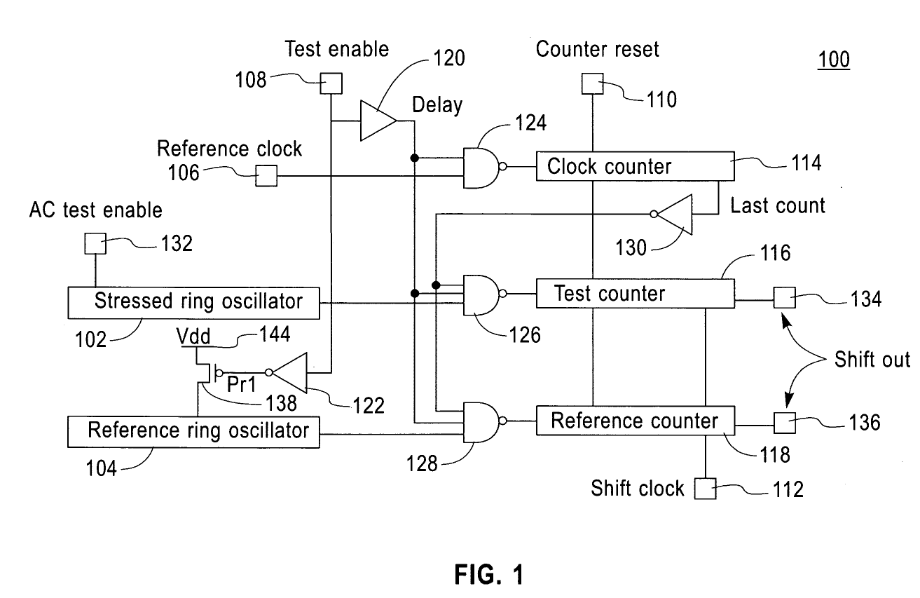

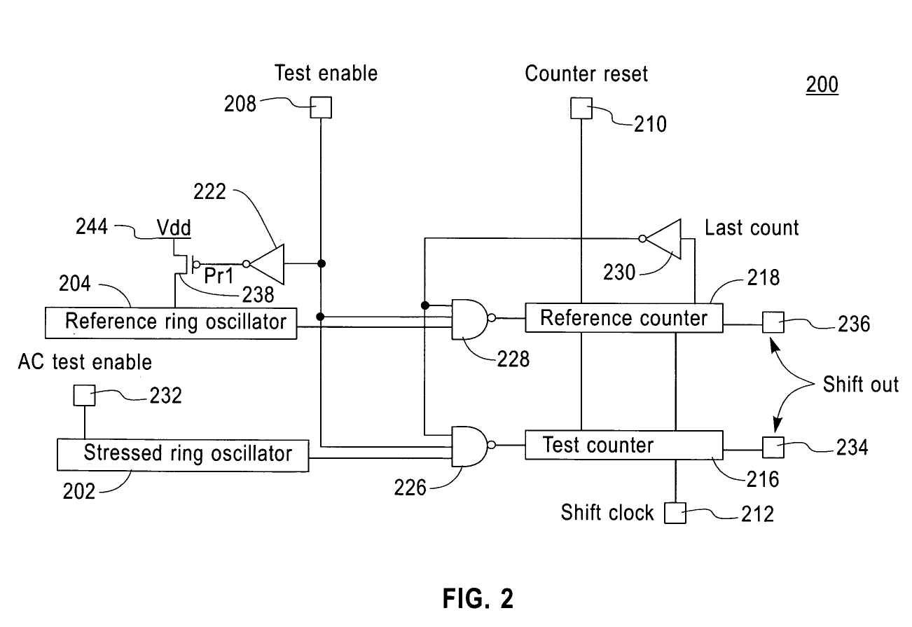

As discussed above, CMOS transistors experience a reduction of drive current after being operated for many hours. FIG. 1 and FIG. 2 show schematic diagrams illustrating exemplary circuits 100, 200 for measuring transistor degradation according to an embodiment of the present invention. Each of the circuits 100, 200 illustrate a different embodiment for measuring transistor degradation. These circuits 100, 200 facilitate the detection and reporting of speed degradation associated with field-installed chips for providing an early warning of speed degradation.

FIG. 1 shows a circuit 100 comprising an on-chip stressed ring oscillator 102 and an on-chip reference ring oscillator 104. An output of the stressed ring oscillator 102 is electrically coupled to a third input of a second NAND gate 126. An output of the reference ring oscillator 104 is electrically coupled to a third input of a third NAND gate 128. The ring oscillators 102, 104 can be constructed from any circuit gates which are susceptible to speed degradation. In one embodiment, the ring oscillators 102, 104 comprise substantially identical components and are a cross-section of the elements included in a representative circuit. In one embodiment, the stressed ring oscillator 102 is continuously supplied voltage and the reference ring oscillator 104 is off except when a test enable input 108 is high. In one embodiment, the test enabled input is placed on-chip and in another embodiment, the test enable input, could be place external or “off chip.” The change in frequency of the stressed ring oscillator 102 compared to the reference ring oscillator 104 is measured by built in on-chip gated counters, e.g., scannable chain of latches, 114, 116, 118 so a digital comparison of frequency can be made. The comparison can be made by any of a variety of circuits and methods including comparators as known to those of average skill in the art.

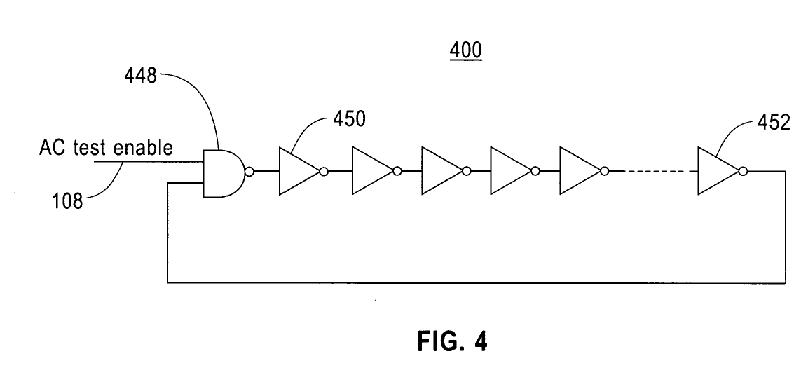

The stress can be applied in either Alternating Current (“AC”) or Direct Current (“DC”) conditions. For example, an AC test enable input 132 is electrically coupled to an input of the stressed ring oscillator 102. When the AC test enable input is high, AC stress is applied, wherein the ring oscillators 102, 104 run at their full frequency, as determined by the intrinsic stage delay and length of the ring 102, 104. When the AC test enable input is low DC stress is applied, wherein the oscillation is blocked, but the voltage remains applied. This applies the same voltage stress to every other gate of an inverting chain. A circuit for selecting the AC or DC mode is further discussed with respect to FIG. 4.

The circuit 100 of FIG. 1 comprises a reference clock input 106, a test enable input 108, a counter rest input 110, and a shift clock input 112. The reference clock input 106 is electrically coupled to a second input of a first NAND gate 124. The test enable input 108 is electrically coupled to an input of a delay element 120 and an input of a first NOT gate 122. The first NOT gate 122 is electrically coupled to a power source 138. A first terminal of the power source is electrically coupled to a voltage drain 144. A second terminal of the power source 138 is electrically coupled to the reference ring oscillator 104.

The output of the delay element 120 is electrically coupled to a first input of the first NAND gate 124, a second input of a second NAND gate, and a second input of a third NAND gate 128. An output of the first NAND gate 124 is electrically coupled to an input of an on-chip clock counter 114. An output of the second NAND gate 126 is electrically coupled to an input of an on-chip test counter 116. An output of the third NAND gate 128 is electrically coupled to an input of an on-chip reference counter 118. The counter reset input 110 is electrically coupled to the plurality of gated counters, i.e., the clock counter 114, the test counter 116, and the reference counter 118.

An output of the clock counter 114 is electrically coupled to an input of a second NOT gate 130. The output of the second NOT gate 130 is electrically coupled to a first input of the second NAND gate 126 and a first input of the third NAND gate 128. The shift clock input 112 is electrically coupled to the reference counter 118 and the test counter 11 6. The shift clock 11 2 shifts out bit sequences 134, 136 from the reference counter 11 8 and test counter 11 6, respectively.

The circuit 100 of FIG. 1 utilizes the reference clock 106 to gate the measurement between the stressed ring oscillator 102 and the reference ring oscillator 104. In one embodiment, the measurement time is fixed by the time it takes to reach a full count in the clock counter 114. The circuit 100 of FIG. 1 provides an absolute measure of the frequency of both ring oscillators because the reference clock 106 runs at a known frequency. It should be noted that the reference clock 106 is not limited to a particular speed. An example of a typical clock speed is 125 MHz.

When the test enable input 108 is high, voltage is applied to the reference ring oscillator 104 and the counters 114, 116, 118 are enabled. A binary signal (e.g., a binary high (1) signal) is propagated to all three NAND gates 124, 126, 128. As the clock counter 114 receives a signal from the reference clock 106 it is updated with a count instance. It should be noted that during a testing period, i.e., while the test enable input 108 is high, the counter reset input 110 is low.

While the test enable input 108 is high a signal is also sent to each of the second NAND gate 126 and third NAND gate 128. When a pulse is generated from the stressed ring oscillator 102 and received at the second NAND gate 126, the test counter 116 receives a signal and increments its counter. When a pulse is generated from the reference ring oscillator 104 and received at the third NAND gate 128, the reference counter 118 receives a signal and increments its counter. Therefore, when the test enable input 108 is high both the test and reference counters 116,118 are incremented.

Referring back to the clock counter 114, the clock counter 114 continues to increment its count until a maximum count is reached, i.e. every bit in the counter 114 is set. Once all the bits are set, the clock counter 114 outputs a last count signal and a binary low (0) signal is propagated to the second and third NAND gates 126, 128, respectively. The second NAND gate 126 sends a signal to the test counter 116, which in turn stops counting. The third NAND gate 128 sends a signal to the reference counter 118, which in turn stops counting. Therefore, when the clock counter 114 is full, which indicates that it has counted for a certain amount of time (e.g., the reference clock period multiplied by the maximum counter value), the test and reference counters 116, 118 no longer receive any signals.

Once the clock counter 114 outputs a last count signal, the shift clock 11 2 can shift out the results 134, 136 from the test counter 116 and the reference counter 118, respectively. The results 134,136 reveal an absolute measure of the frequency associated with the stressed ring oscillator 102 and the reference ring oscillator 104. The counters 114, 116, 118 can be reset by changing the state of the clock reset input 110 from low to high.

FIG. 2 shows another circuit 200 for measuring the degradation of transistors. The circuit of FIG. 2 utilizes a reference ring oscillator 204 to gate the measurement of the frequency change between the stressed ring oscillator 202 and the reference ring oscillator 204. Similar to the circuit 100 of FIG. 1, the circuit 200 of FIG. 2 comprises the stressed ring oscillator 202 and the reference ring oscillator 204. However, the circuit 200 of FIG. 2 does not include the reference clock input and utilizes the reference ring oscillator 204 to yield a relative measure of frequency for the stressed ring oscillator 202. An output of the stressed ring oscillator 202 is electrically coupled to a third input of a first NAND gate 226. An output of the reference ring oscillator 204 is electrically coupled to a third input of a second NAND gate 228. The circuit 200 includes the test enable input 208, counter reset input 210, and shift clock input 212.

Similar to the circuit 100 of FIG. 1, the stressed ring oscillator 202 is continuously supplied voltage and the reference ring oscillator 204 is off except when the test enable input 208 is high. The test counter 216 and reference counter 218 measures the change in frequency of the stressed ring oscillator 202 compared to the reference ring oscillator 204. The AC test enable 232, as discussed above, applies an AC stress when its state is high and a DC stress when its state is low.

The test enable input 208 is electrically coupled to an input of a first NOT gate 222. The first NOT gate 222 is electrically coupled to the control gate of a power source 244. A first terminal of the power source 238 is electrically coupled to a voltage drain 244. A second terminal of the power source 238 is electrically coupled to the reference ring oscillator 204. The test enable input 208 is also electrically coupled to a second input of the first NAND gate 226 and a second input of the second NAND date 228. An output of the first NAND gate 226 is electrically coupled to an input of the reference counter 218. An output of the second NAND gate 228 is electrically coupled to an input of a test counter 216. The counter reset input 210 is electrically coupled to the reference counter 218 and the test counter 216.

An output of the reference counter 218 is electrically coupled to an input of a second NOT gate 230. The output of the second NOT gate 230 is electrically coupled to a first input of the first NAND gate 226 and a first input of the second NAND gate 228. The shift clock input 212 is electrically coupled to the test counter 216 and the reference counter 218. The shift clock 212 shifts out bit sequences 234, 236 from the reference counter 218 and test counter 216, respectively.

When the test enable input 208 is high, the counter reset input 210 is set to low. The NOT gate 222 receives a signal from the test enable input 208, which powers on the reference ring oscillator 204. The first NAND gate 226 also receives a signal from the test enable input 208, which in turn initiates counting at the reference counter 218. As the reference ring oscillator 204 pulses the reference counter 218 receives each pulse from the first NAND gate 226 and increments its counter. As the stressed ring oscillator 202 pulses the test counter 216 receives each pulse from the second NAND gate 228 and increments its counter. The reference counter 218 continues to increment its count until all bits are set. When the highest bit is set, the reference counter 218 outputs a last count signal, e.g., a binary 0 signal, to the second NAND gate 228. This stops the counting at the test counter 216. Once the reference counter outputs a last count signal, the shift clock 212 can shift out the results 234, 236 from the test counter 216 and the reference counter 218, respectively. The results 234, 236 reveal a relative measurement of the frequency change between the stressed ring oscillator 202 and the reference ring oscillator 204.

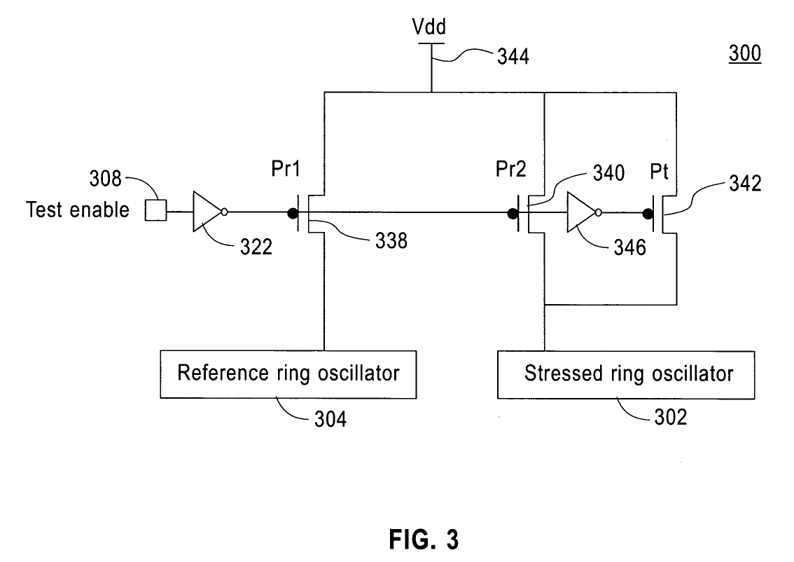

FIG. 3 shows a schematic of a circuit 300 that can be used to supply power to the circuits 100, 200 of FIG. 1 and FIG. 2. The circuit 300 of FIG. 3 shows the test enable input 308 electrically coupled to a first NOT gate 322. The output of the first NOT gate 322 is electrically coupled to the control gate of a first power source 338, a second power source 340, and a second NOT gate 346. The output of the second NOT gate 346 is electrically coupled to the control gate of a third power source 342 A first terminal of each of the power sources 338, 340, 342 is electrically coupled to a voltage drain 344. A second terminal of the first power source 338 is electrically coupled to the reference ring oscillator 304 and the second terminal of the second power source 340 is electrically coupled to the stressed ring oscillator 302. The second terminal of the second power source 340 is also electrically coupled to the second terminal of the third power source 342. One advantage of the circuit 300 of FIG. 3 is that it reduces the impact of any voltage drop across the first power source 338 by supplying power to the stressed ring oscillator 302 through a substantially identical power source 340. The power is supplied to the stressed ring oscillator 302 through the substantially identical power source 340 while the test enable input 308 is high or through the third power source 342 while the test enable input 308 is low.

FIG. 4 is a schematic of a circuit 400 for selecting an AC or DC test mode. It should be noted that the circuit of FIG. 4 is not limited to the NAND gate and NOT gates shown. Other degradation-susceptible delay elements can be used in combination with other AC/DC selection devices such that the entire path inverts the signal. These components are used for illustrative purposes only. In one embodiment, each of the ring oscillators 102, 104 comprises the circuit of FIG. 4. FIG. 4 shows the AC test enable 132 electrically coupled to a NAND gate. The output of the NAND gate is electrically coupled to a NOT gate 450. FIG. 4 shows the plurality of NOT gate gates 450 connected in series, wherein a last NOT gate 452 is electrically coupled to a second input of the NAND gate 448. Asserting the AC test enable 132 high closes the loop of the respective ring oscillator 102, 104 and allows it to run. Asserting the AC test 132 low opens the loop and holds the ring oscillators 102, 104 in a fixed, i.e., DC, state.

Process Of Testing A Circuit For Transistor Degradation

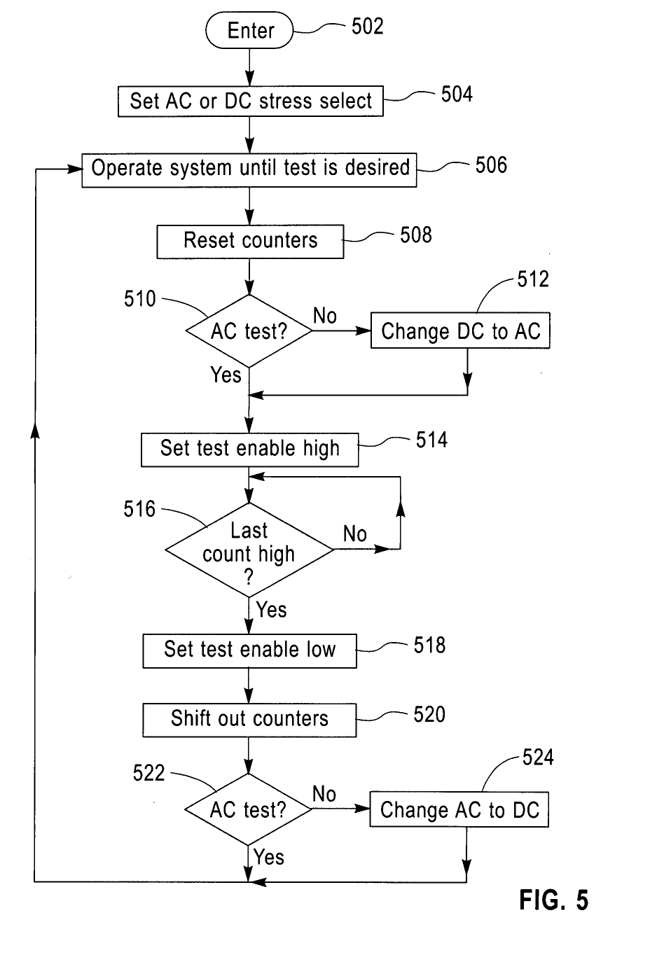

FIG. 5 is an operational diagram illustrating an exemplary process of testing a circuit for transistor degradation. The operational flow diagram of FIG. 5 begins at step 502 and flows directly to step 504. The AC or DC stress mode, at step 504, is selected. For example, the AC test enable 132 is set high for an AC stress mode or is set low for a DC stress mode. A system comprising the test circuit, at step 506, is operated until testing of the circuit is desired. The counters 114,116, 118 (or 116, 118), at step 508, are reset. For example, the counter reset input 110 is set high.

The system, at step 510, determines whether the AC test mode was selected. If the result of this determination is negative (e.g., the DC stress mode was selected), the DC stress mode is changed to the AC stress mode. Unlike hot carrier injection (“HCI”), where the magnitude of the degradation is proportional to the number of switching cycles, NBTI degradation is proportional to the amount of time the PMOS is on in steady state. Therefore, DC (steady state) circuit NBTI is worse than AC (non-steady state) circuit NBTI operation. The present invention monitors both types of degradation depending on the application condition of the chip being monitored. For example, a micro processor chip that spends a majority of time in sleep mode (but full Vdd applied), the DC stress mode is more relevant.

The control then flows to step 514. If the result of the determination is positive, the test enable input 108, at step 514, is set to high. The system determines, at step 516, if the last count in either the clock counter 114 or reference counter 118 is high. If the result of this determination is negative, the control returns back to step 514. If the result of this determination is positive, the test enable input 108, at step 518, is set to low. The shift clock 112, at step 520, shift out the counters 114, 116, 118 (or 116, 118). The system, at step 522, determines whether the AC test mode was selected. If the result of this determination is negative, the DC stress mode is changed to the AC stress mode. The control then flows to step 506. If the result of the determination is positive, the control then flows to step 506.

### NON-LIMITING EXAMPLES

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. An on-chip circuit for monitoring transistor degradation, the circuit comprising:
an on-chip reference ring oscillator electrically coupled to an on-chip reference counter;
an on-chip stressed ring oscillator electrically coupled to an on-chip test counter;
a test enable input electrically coupled with the reference counter, the test counter, and the reference ring oscillator, whereby when the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter, and wherein a difference in bit sequence between the reference counter and the test counter is compared to determine a relative difference there between.

2. The circuit of claim 1, further comprising:
an on-chip counter reset pin electrically coupled to the reference counter and the test counter, wherein when the counter reset pin is asserted each of the reference counter and test counter is reset.

3. The circuit of claim 1, wherein each of the reference counter and the test counter is a scannable chain of latches.

4. The circuit of claim 1, further comprising:
a NOT gate electrically coupled to an output of the reference counter and an input of a first NAND gate and an input of a second NAND gate, wherein the first NAND gate is electrically coupled to an input of the reference counter and the second NAND gate is electrically coupled to an input of the test counter, and wherein when a last count signal from the reference counter is received by the NOT gate, each of the reference counter and the test counter stop counting.

5. The circuit of claim 1, further comprising:
a shift clock input electrically coupled to each of the reference counter and test counter, wherein when the shift clock input is applied a set of bits are shifted out the reference counter and the test counter.

6. The circuit of claim 1, further comprising:
at least a first power source electrically coupled to the reference ring oscillator, wherein the first power source supplies power to the reference ring oscillator when the test enable input is asserted;
a test switch electrically coupled to the stressed ring oscillator and at least a second power source, wherein the second power source constantly supplies voltage to the stressed ring oscillator, and wherein when the test switch receives a first voltage level, an AC control operates the stressed ring oscillator in a free-running mode, and wherein when the test switch receives a second voltage level, a DC control operates the stressed ring oscillator in a static mode.

7. The circuit of claim 1, further comprising:
a clock counter electrically coupled to the reference counter and the test counter;
a reference clock electrically coupled to the clock counter, wherein the test enable input is further electrically coupled to the clock counter, and wherein when the test enable input is asserted the clock counter counts for a given amount of time, wherein the reference ring oscillator places a bit sequence proportional to the reference ring oscillator frequency on the reference counter simultaneously while the stressed ring oscillator places bit sequence proportional to the stressed ring oscillator frequency on the test counter, and wherein a last bit in the clock counter is set, the clock counter, test counter, and reference counter stop counting and the difference in bit sequence between the reference counter and the test counter is compared to determine an absolute difference there between.

8. An on-chip method for monitoring transistor degradation, the method comprising:
electrically coupling an on-chip reference ring oscillator to an on-chip reference counter;
electrically coupling an on-chip stressed ring oscillator to an on-chip test counter;
electrically coupling a test enable input with the reference counter, the test counter, and the reference ring oscillator;
asserting the test enable input, wherein when the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter;
comparing a difference in bit sequence between the reference counter and the test counter; and
determining, in response to the comparing, a relative difference between the frequency of the reference counter and the frequency of the test counter.

9. The method of claim 8, further comprising:
electrically coupling a counter reset pin to the reference counter and the test counter;
asserting the counter reset pin; and
resetting, in response to asserting the counter reset pin, the reference counter and the test counter.

10. The method of claim 8, wherein each of the reference counter and the test counter is a scannable chain of latches.

11. The method of claim 8, further comprising:
electrically coupling a NOT gate to an output of the reference counter and an input of a first NAND gate and an input of a second NAND gate;
electrically coupling the first NAND gate to an input of the reference counter;
electrically coupling a second NAND gate to an input of the test counter;
receiving, by the NOT gate, a last count signal from the reference counter, wherein when the last count signal is received by the NOT gate, each of the reference counter and the test counter stop counting.

12. The method of claim 8, further comprising:
electrically coupling a shift clock input to each of the reference counter and test counter;
asserting the shift clock input; and
shifting out, in response to the asserting, a set of bits is shifted out the reference counter and the test counter.

13. The method of claim 8, further comprising:
electrically coupling at least a first power source to the reference ring oscillator;
supplying, by the first power source, power to the reference ring oscillator in response to asserting the test enable input;
electrically coupling a test switch to the stressed ring oscillator and at least a second power source;
constantly supplying power, by the second power source, to the stressed ring oscillator;
receiving, by the test switch, a first voltage level;
operating, by an AC control, the stressed ring oscillator in a free-running mode in response to the test switch receiving the first voltage level;
receiving, by the test switch, a second voltage level; and
operating, by a DC control, the stressed ring oscillator in a static mode in response to the test switch receiving the second voltage.

14. The method of claim 8, further comprising:
electrically coupling a clock counter to the reference counter and the test counter;
electrically coupling a reference clock to the clock counter;
electrically coupling the test enable input to the clock counter;
counting, by the clock counter, for a given amount of time in response to asserting the test enable input;
placing, by the reference ring oscillator a bit sequence proportional to the reference ring oscillator frequency on the reference counter simultaneously while the stressed ring oscillator places bit sequence proportional to the stressed ring oscillator frequency on the test counter, and wherein a last bit in the clock counter is set, the clock counter, test counter, and reference counter stop counting;
comparing a difference in bit sequence between the reference counter and the test counter; and
determining, in response to the comparing, an absolute difference between the frequency of the reference counter and the frequency of the test counter.

15. A computer readable medium for on-chip monitoring of transistor degradation, the computer readable medium comprising instructions for:
electrically coupling an on-chip reference ring oscillator to an on-chip reference counter;
electrically coupling an on-chip stressed ring oscillator to an on-chip test counter;
electrically coupling a test enable input with the reference counter, the test counter, and the reference ring oscillator;
asserting the test enable input, wherein when the test enable input is asserted the reference ring oscillator places a bit sequence proportional to the reference ring oscillator frequency on the reference counter simultaneously while the stressed ring oscillator places bit sequence proportional to the stressed ring oscillator frequency on the test counter;
comparing a difference in bit sequence between the reference counter and the test counter; and
determining, in response to the comparing, a relative difference between the frequency of the reference counter and the frequency of the test counter.

16. The computer readable medium of claim 15, further comprising instructions for:
electrically coupling a counter reset pin to the reference counter and the test counter;
asserting the counter reset pin; and
resetting, in response to asserting the counter reset pin, the reference counter and the test counter.

17. The computer readable medium of claim 15, further comprising instructions for:
electrically coupling a NOT gate to an output of the reference counter and an input of a first NAND gate and an input of a second NAND gate;
electrically coupling the first NAND gate to an input of the reference counter;
electrically coupling a second NAND gate to an input of the test counter;
receiving, by the NOT gate, a last count signal from the reference counter, wherein when the last count signal is received by the NOT gate, each of the reference counter and the test counter stop counting.

18. The computer readable medium of claim 15, further comprising instructions for:
electrically coupling a shift clock input to each of the reference counter and test counter;
asserting the shift clock input; and
shifting out, in response to the asserting, a set of bits is shifted out the reference counter and the test counter.

19. The computer readable medium of claim 15, further comprising instructions for:
electrically coupling at least a first power source to the reference ring oscillator;
supplying, by the first power source, power to the reference ring oscillator in response to asserting the test enable input;
electrically coupling a test switch to the stressed ring oscillator and at least a second power source;
constantly supplying power, by the second power source, to the stressed ring oscillator;
receiving, by the test switch, a first voltage level;
operating, by an AC control, the stressed ring oscillator in a free-running mode in response to the test switch receiving the first voltage level;
receiving, by the test switch, a second voltage level; and
operating, by a DC control, the stressed ring oscillator in a static mode in response to the test switch receiving the second voltage.

20. The computer readable medium of claim 15, further comprising instructions for:
electrically coupling a clock counter to the reference counter and the test counter;
electrically coupling a reference clock to the clock counter;
electrically coupling the test enable input to the clock counter;
counting, by the clock counter, for a given amount of time in response to asserting the test enable input;
placing, by the reference ring oscillator a bit sequence proportional to the reference ring oscillator frequency on the reference counter simultaneously while the stressed ring oscillator places bit sequence proportional to the stressed ring oscillator frequency on the test counter, and wherein a last bit in the clock counter is set, the clock counter, test counter, and reference counter stop counting;
comparing a difference in bit sequence between the reference counter and the test counter; and
determining, in response to the comparing, an absolute difference between the frequency of the reference counter and the frequency of the test counter.
